(19) United States
(12) Patent Application Publication
(10) Pub. No.: US 2009/0117751 A1
(43) Pub. Date: May 7, 2009

(54) METHOD FOR FORMING RADICAL OXIDE LAYER AND METHOD FOR FORMING DUAL GATE OXIDE LAYER USING THE SAME

(75) Inventors: Yong-Soo KIM, Ichon-shi (KR); Hong-Seon Yang, Ichon-shi (KR); Heung-Jae Cho, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/163,911

(22) Filed: Jun. 27, 2008

(30) Foreign Application Priority Data
Nov. 2, 2007 (KR) 10-2007-0111728

(51) Int. Cl. H01L 21/469

(52) U.S. Cl. 438/788; 257/E21.285

(57) ABSTRACT

A method for fabricating a radical oxide layer includes providing a substrate, forming an oxide layer over the substrate through a radical oxidation process, and performing a thermal treatment on the oxide layer by using oxygen (O₂).

### CROSS-REFERENCE TO RELATED APPLICATIONS

The present invention claims priority of Korean patent application number 2007-0111728, filed on Nov. 2, 2007, which is incorporated by reference in its entirety.

### BACKGROUND OF THE INVENTION

The present invention relates to a method for fabricating a semiconductor device and, more particularly, to a method for forming a radical oxide layer and a method for forming a dual gate oxide layer using the same.

A gate oxide layer in a typical dynamic random access memory (DRAM) device or a tunnel oxide layer in a typical flash memory device is formed through a dry oxidation or a wet oxidation process. Recently, to decrease the formation of electron traps in an oxide layer during the dry or wet oxidation process, a radical oxidation process using an oxygen radical and a hydrogen radical is performed to form the gate oxide layer or the tunnel oxide layer. It is well known that the oxide layer formed by the radical oxidation process, which will be referred to as a radical oxide layer hereinafter, has improved electric and physical characteristics compared to that formed by the dry or wet oxidation process.

FIG. 1 illustrates a defect bond in a typical radical oxide layer.

Referring to FIG. 1, since the hydrogen radical used for the radical oxidation process has a very high reactivity, it causes a H-based defective bond (e.g., an Si—OH bond or a Si—H bond) in the radical oxide layer.

Recently, gate oxide layers in a transistor are formed to have different thicknesses to embody circuits having various operation voltages in one chip. Thus, a dual gate oxide layer formation process for high speed operation of the device is widely used by forming the gate oxide layer in different thicknesses in different regions, e.g., a cell region and a peripheral region. For instance, the gate oxide layer is formed to have a relatively thick thickness in the cell region compared to that in the peripheral region.

FIGS. 2A to 2F are cross-sectional views illustrating a method for forming a typical dual gate oxide layer.

Referring to FIG. 2A, a first oxide layer 21 is formed through a first radical oxidation process over a substrates 20 having first region A for a relatively thick oxide layer and second region B for a relatively thin oxide layer

Referring to 2B, a photoresist pattern 22 is formed over the first oxide layer 21 which leaves the second region B exposed.

Referring to FIGS. 2C and 2D, the first oxide layer 21 in the second region B is removed using the photoresist pattern 22 as a barrier. Then, the photoresist pattern 22 is removed. The first oxide layer 21 (exposed sections) and photoresist pattern 22 are removed using a wet chemical such as BOE (ammonium fluoride (NH₄F)+hydrogen fluoride (HF)) or CLN B (sulfuric acid (H₂SO₄)+hydrogen peroxide (H₂O₂)+water (H₂O)).

Referring to FIG. 2E, a second radical oxidation process is performed to form a second oxide layer 23 over the substrate 20 in the second region B. The second oxide layer 23 is thinner than the first oxide layer 21 in the first region A. Although not shown, an oxide layer can be additionally formed over the first oxide layer 21 in the first region A during the radical oxidation process. In this case, the thickness of the oxide layer in the first region A increases.

Referring to FIG. 2F, a gate electrode 24 including polysilicon is formed over the first and second oxide layers 21 and 23.

However, the typical radical oxidation process has the following limitations.

Since the first oxide layer 21 is formed through the radical oxidation process using H₂ and O₂, as described referring to FIG. 1, the H-based defective bond occurs in the first oxide layer 21. Thus, when the first oxide layer 21 and photoresist pattern 22 are removed (refer to FIGS. 2C and 2D), the first oxide layer 21 may be attacked by the wet chemical and damaged because of the defective bonds.

### SUMMARY OF THE INVENTION

Embodiments of the present invention are directed to a method for forming a radical oxide layer and a method for forming a dual gate oxide layer using the same. In this invention, a defective bond in a radical oxide layer is removed to minimize a loss of the radical oxidation layer caused by a wet chemical during the dual gate oxide layer formation process.

In accordance with an aspect of the present invention, there is provided a method for fabricating a radical oxide layer. The method includes providing a substrate, forming an oxide layer over the substrate through a radical oxidation process, and performing a thermal treatment on the oxide layer by using oxygen (O₂).

In accordance with another aspect of the present invention, there is provided a method for fabricating a dual gate oxide layer. The method includes providing a substrate having a first region for a relatively thick oxide layer and a second region for a relatively thin oxide layer, forming a first oxide layer over the substrate through a first radical oxidation process, performing a thermal treatment using O₂ on the first oxide layer, selectively removing the first oxide layer in the second region, and performing a second radical oxidation process to form a second oxide layer over the substrate in the second region.

### BRIEF DESCRIPTION OF THE DRAWINGS

FIG. 1 illustrates a defect bond in a typical radical oxide layer.

FIGS. 2A to 2F are cross-sectional views illustrating a method for forming a typical dual gate oxide layer.

FIGS. 3A to 3F are cross-sectional views illustrating a method for forming a dual gate oxide layer in accordance with an embodiment of the present invention.

FIG. 4 illustrates a radical oxide layer from which defective bonds are removed in accordance with an embodiment of the present invention.

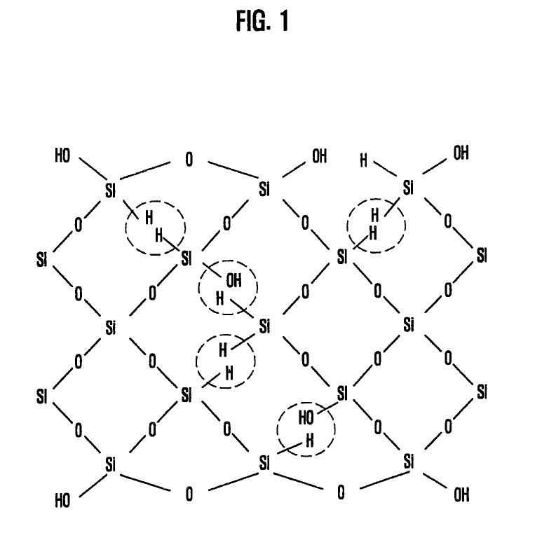

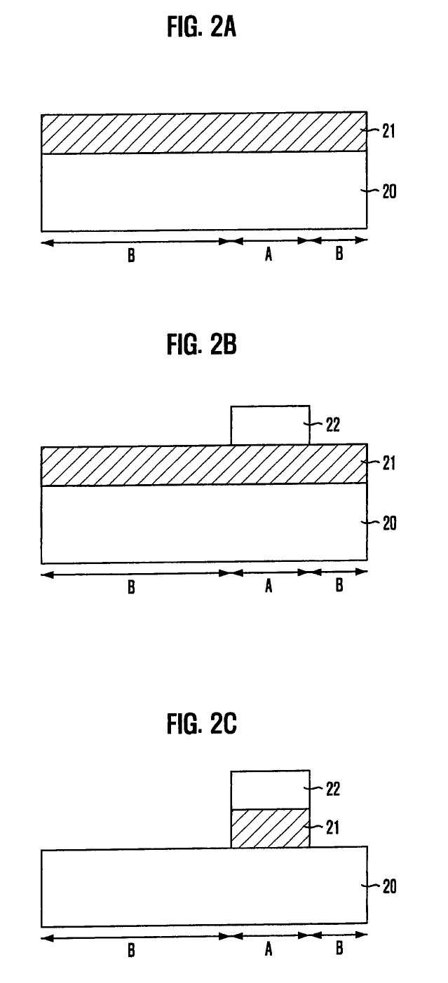

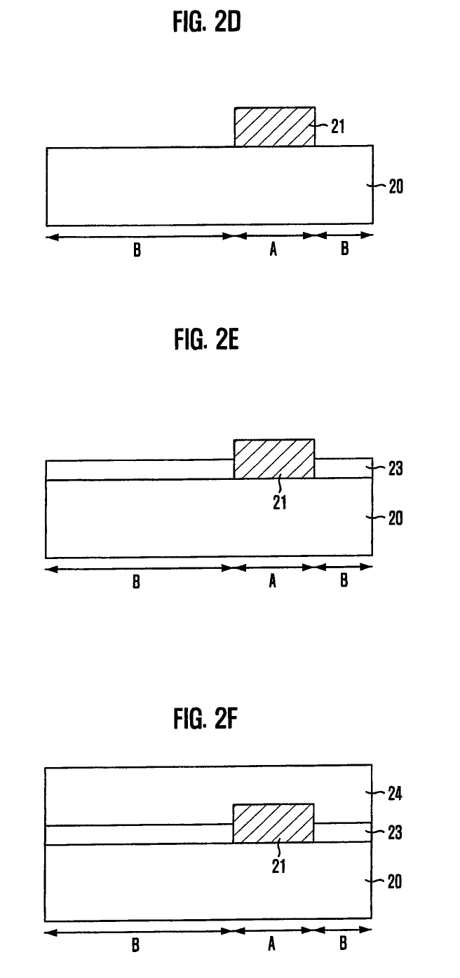

### DESCRIPTION OF SPECIFIC EMBODIMENTS

Embodiments of the present invention relate to a method for forming a radical oxide layer and a method for forming a dual gate oxide layer using the same.

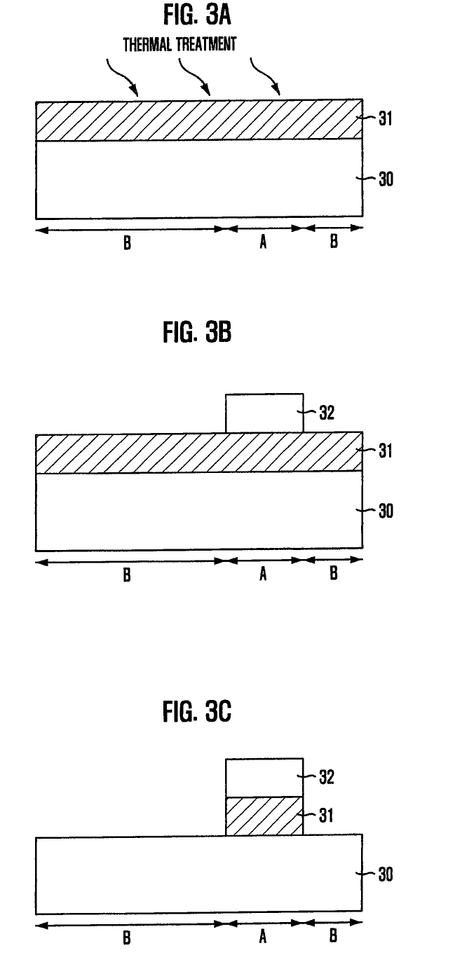

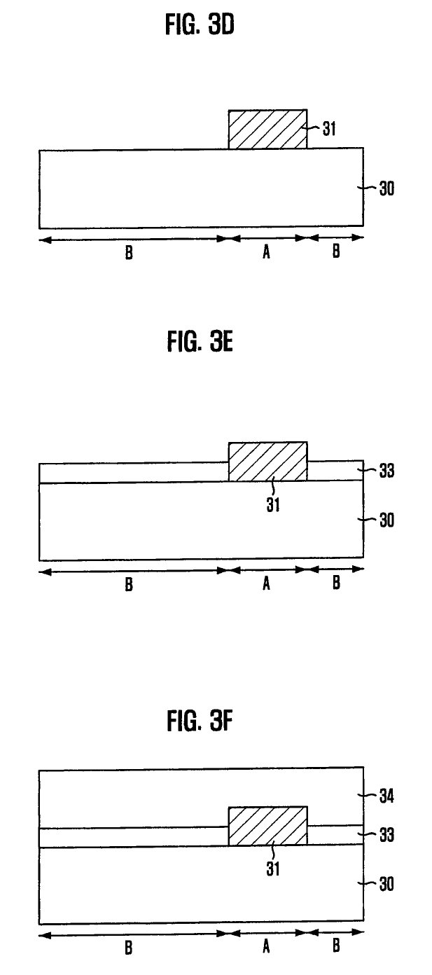

FIGS. 3A to 3F are cross-sectional views illustrating a method for forming a dual gate oxide layer in accordance with an embodiment of the present invention.

Referring to FIG. 3A, a first oxide layer 31 is formed through a first radical oxidation process over a substrates 30 having first region A for a relatively thick oxide layer and second region B for a relatively thin oxide layer. A first oxide layer 31 is formed over the substrate 30 by a first radical oxidation process. The first oxide layer 31 may be formed to have a thickness of approximately 20 Å to approximately 100 Å. The first radical oxidation process may be performed using a thermal oxidation method or a plasma oxidation method. When the first radical oxidation process is performed using the thermal oxidation method, a temperature higher than approximately 700° C. may be used with a pressure not higher than approximately 0.5 Torr, and a gas mixture of H₂ and O₂ or D₂ and O₂.

When the first radical oxidation process is performed using the plasma oxidation method, an O₂ containing gas [e.g., O₂, H₂O, oxidane (D₂O), nitric oxide (NO), or nitrous oxide (N₂O) to a plasma of inert gas [e.g., argon (Ar) or xenon (Xe)] may be used at a temperature not higher than approximately 700° C. and at a pressure not higher than approximately 300 Torr.

A H-based defect bond may be caused in the first oxide layer 31 formed by the first radical oxidation process. Thus, the first oxide layer 31 may be easily damaged when it is attacked by a wet chemical in a subsequent process. To remove the defective bonds in the first oxide layer 31, a thermal process using O₂ is performed after the first oxide layer 31 is formed.

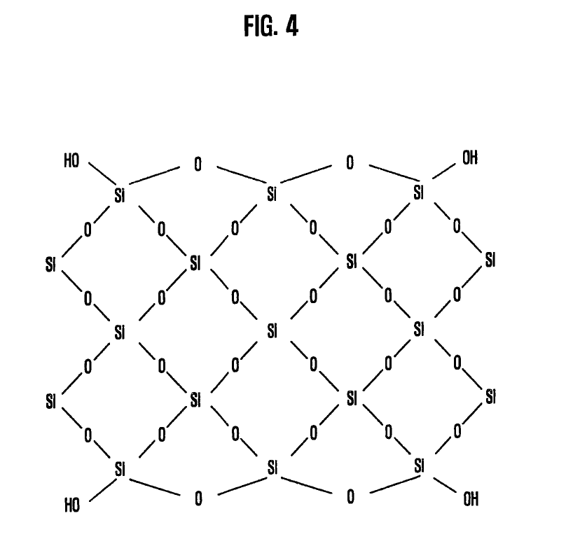

FIG. 4 illustrates a radical oxide layer from which defective bonds are removed in accordance with an embodiment of the present invention. When the thermal process using O₂ is performed on the first oxide layer 31, the H-based defect bond is removed. Herein, the thermal process can be performed by adding the inert gas (e.g., Ar or Xe) at a temperature of approximately 700° C. to approximately 1,000° C. This thermal process may also be performed by providing O₂ gas to plasma of a rare gas (e.g., the Ar or Xe) at a temperature not higher than approximately 700° C.

The thermal process can be performed by the aforementioned first radical oxidation process and in-situ.

Referring to FIG. 3B, a photoresist pattern 32 is formed over the first oxide layer 31 leaving the second region B exposed.

Referring to FIGS. 3C and 3D, the first oxide layer 31 in the second region B is removed using the photoresist pattern 32 as a barrier. Then, the remaining photoresist pattern 32 is removed. The first oxide layer 31 (exposed sections) and photoresist pattern 32 are removed using a wet chemical such as BOE (NH₄F+HF) or CLN B(H₂SO₄+H₂O₂+H₂O). The defect bonds in the first oxide layer 31 has been removed using the thermal method. Thus, although a wet chemical process is performed, loss of the first oxide layer 31 can be minimized.

Referring to FIG. 3E, a second radical oxidation process is performed to form a second oxide layer 33 thinner than the first oxide 31 layer in the first region A. The second oxide layer 33 is formed to have a thickness of approximately 20 Å to approximately 100 Å. The second radical oxidation process is performed through the same process as the first radical oxidation process. Although not shown, an oxide layer can be additionally formed over the first oxide layer 31 in the first region A during the radical oxidation process. In this case, the thickness of the oxide layer in the first region A increases.

Referring to FIG. 3F, a gate electrode 3 including polysilicon is formed over the first and second oxide layers 31 and 33. A nitridation process can be performed on a surface of the first and second oxide layers 31 and 33 before formation of the gate electrode 34 to prevent impurities doped into the polysilicon in the gate electrode 34 from diffusing into a channel region during a subsequent process. The nitridation process can be performed by implanting N₂ gas to plasma of an inert gas (e.g., Ar and Xe).

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a radical oxide layer, the method comprising:
providing a substrate;
forming an oxide layer over the substrate through a radical oxidation process; and
performing a thermal treatment on the oxide layer by using oxygen (O₂).

2. The method of claim 1, wherein the radical oxidation process is performed using a thermal oxidation method or a plasma oxidation method.

3. The method of claim 2, wherein the radical oxidation process using the thermal oxidation method is performed using a gas mixture of hydrogen (H₂)/O₂ or D₂/O₂ at a temperature higher than 700° C. at a pressure not higher than 0.5 Torr.

4. The method of claim 2, wherein the radical oxidation process using the plasma oxidation method is performed by providing O containing gas to inert gas plasma at a temperature not higher than 700° C. at a pressure not higher than 300 Torr.

5. The method of claim 4, wherein the inert gas is argon (Ar) or xenon (Xe), and the O containing gas is O₂, dihydrogen monoxide (H₂O), oxidane (D₂O), nitric oxide (NO), or nitrous oxide (N₂O).

6. The method of claim 1, wherein the thermal treatment is performed at a temperature of 700° C. to 1,000° C.

7. The method of claim 6, wherein the thermal process is performed by adding the inert gas.

8. The method of claim 1, wherein the thermal treatment is performed using the inert gas plasma at a temperature not higher than 700° C.

9. The method of claim 7, wherein the inert gas is argon (Ar) or xenon (Xe), or both.

10. The method of claim 8, wherein the inert gas includes argon (Ar) or xenon (Xe), or both.

11. A method for fabricating a dual gate oxide layer, the method comprising:
providing a substrate having a first region and a second region;
forming a first oxide layer over the substrate through a first radical oxidation process;
performing a thermal treatment using O₂ on the first oxide layer;
selectively removing the first oxide layer in the second region while leaving the first oxide layer in the first region; and
performing a second radical oxidation process to form a second oxide layer over the substrate in the second region, wherein the second oxide layer is thinner than the first oxide layer.

12. The method of claim 11, wherein the first or second radical oxidation process is performed through a thermal oxidation method or a plasma oxidation method.

13. The method of claim 12, wherein the first or second radical oxidation process is performed using a gas mixture of H₂/O₂ or D₂/O₂ at a temperature higher than approximately 700° C. at a pressure not higher than 0.5 Torr.

14. The method of claim 12, wherein the first or second radical oxidation process is performed by implanting O containing gas to a inert gas plasma at a temperature not higher than approximately 700° C. at a pressure not higher than approximately 300 Torr.

15. The method of claim 14, wherein the inert gas includes Ar or Xe, or both, and the O containing gas includes O₂, H₂O, D₂O, or N₂O, or a combination thereof.

16. The method of claim 11, wherein the thermal treatment is performed at a temperature of 700° C. to 1,000° C.

17. The method of claim 11, wherein the thermal process is performed by adding the inert gas.

18. The method of claim 11, wherein the thermal treatment is performed using inert gas plasma at a temperature not higher than 700° C.

19. The method of claim 17, wherein the inert gas includes Ar or Xe, or both.

20. The method of claim 18, wherein the inert gas includes Ar or Xe, or both.

21. The method of claim 11, wherein selectively removing the first oxide layer is performed using a wet chemical.

22. The method of claim 11, further comprising performing a nitridation process on a resultant surface after forming the second oxide layer.

23. The method of claim 22, wherein the nitridation process is performed by adding N₂ gas to the inert gas plasma.
